(19) United States
(12) Patent Application Publication
(10) Pub. No.: US 2017/0005032 A1
(43) Pub. Date: Jan. 5, 2017

(54) LEAD FRAME AND STACK PACKAGE MODULE INCLUDING THE SAME

(71) Applicant: SAMSUNG ELECTRO-MECHANICS CO., LTD., Suwon-si (KR)

(72) Inventors: Jin Su KIM, Suwon-si (KR); Tae Gu KIM, Suwon-si (KR); Sung Ho KIM, Suwon-si (KR)

(73) Assignee: SAMSUNG ELECTRO-MECHANICS CO., LTD., Suwon-si (KR)

(21) Appl. No.: 14/991,589

(22) Filed: Jan. 8, 2016

(30) Foreign Application Priority Data
Jun. 30, 2015 (KR) 10-2015-0092902

(51) Int. Cl. H01L 23/495; H01L 23/00; H01L 25/065

(52) U.S. Cl. CPC H01L 23/49551; H01L 23/49513; H01L 23/49524; H01L 23/49575; H01L 25/0657; H01L 25/0652; H01L 24/33; H01L 2224/32245; H01L 2924/152

(57) ABSTRACT

A lead frame and a stack package module including the same are provided. The lead frame including a lower-end coupling portion coupled to a lower package through soldering, and an upper-end connecting portion contacting a side surface groove formed in a side surface of an upper package to support the upper package.

### CROSS-REFERENCE TO RELATED APPLICATION

This application claims the benefit under 35 USC 119(a) of Korean Patent Application No. 10-2015-0092902 filed on Jun. 30, 2015, in the Korean Intellectual Property Office, the entire disclosure of which is incorporated herein by reference for all purposes.

### BACKGROUND

1. Field

The following description relates to a lead frame and a stack package module, and to a lead frame connecting upper and lower packages to each other and a stack package frame including the same.

2. Description of Related Art

To support the multi-functionality of modern electronic products, a larger number of electronic elements are integrated into a single substrate. However, limitations exist in the number of elements that can be packed into a single substrate. Thus, researches are being performed to develop technologies that allow integrating a large number of elements in a limited space.

One of such researches involves a package-on-package (POP) module constituting a new package by stacking a package on another package in addition to mounting several electronic components in a single package.

In the package-on-package module, in order to connect upper and lower packages to each other, a copper (Cu) pin is adhered to each of the upper and lower packages through soldering.

However, in order to connect the upper and lower packages to each other through soldering using the copper pin, or the like, a land for soldering should be formed in a lower surface of the upper package, and it is difficult and costly to couple the land and the copper pin through soldering on the lower surface of the upper package.

Further, when warpage occurs in the upper or lower package, an open-circuit may occur in the upper or lower package connected to the copper pin.

Therefore, it is desirable to develop lead frames and stack package modules that ameliorate the production issues and improves reliability.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a lead frame includes a lower-end coupling portion coupled to a lower package through soldering, and an upper-end connecting portion contacting a side surface groove formed in a side surface of an upper package to support the upper package.

The general aspect of the lead frame may further include an intermediate seating portion disposed between the lower-end coupling portion and the upper-end connecting portion, the intermediate seating portion protruding in a direction different from a reference direction perpendicular to an upper surface of the lower package so as to allow the upper package to be seated thereon.

The intermediate seating portion may be closer to the upper-end connecting portion than the lower-end coupling portion.

The intermediate seating portion may be formed so that the lower-end coupling portion and the upper-end connecting portion are aligned along a same axis in the reference direction, and the intermediate seating portion may protrude toward the upper package.

The intermediate seating portion may have a laid “U” shape or a laid “I” shape.

The intermediate seating portion may include an inclined portion that is inclined with respect to the reference direction so that the lower-end coupling portion is positioned inwardly of the upper-end connecting portion in a direction parallel with the upper package.

The upper-end connecting portion may be inclined toward the upper package from a reference direction perpendicular to an upper surface of the lower package.

The upper-end connecting portion may be coupled to the side surface groove through soldering.

In another general aspect, a stack package module includes a lower package, an upper package having a width narrower than a width of the lower package, and the general aspect of a lead frame described above.

The lead frame may include a bar member or an angular rod member.

The lead frame may have a length longer than a maximum thickness of elements mounted on an upper surface of the lower package in a reference direction perpendicular to the upper surface of the lower package.

A plurality of upper packages may be disposed above the lower package.

The upper packages may be each supported by corresponding lead frames, and lower-end coupling portions extended from upper-end connecting portions contacting two adjacent upper packages among the plurality of upper packages may be connected to each other.

Elements may be mounted on one surface or both surfaces of the upper package.

In another general aspect, a stack package module includes a first package, a second package dispose above the first package, the second package including a side surface groove, and a lead frame coupled to the first package and extending to the side surface groove of the second package to support the second package above the first package.

The lead frame may include an intermediate seating portion protruding toward a side direction to support the second package.

The intermediate seating portion may include a bent portion having at least one of a laid “U” shape, an inclined portion and a laid “I” shape.

Other features and aspects will be apparent from the following detailed description, the drawings, and the claims.

### BRIEF DESCRIPTION OF DRAWINGS

FIG. 1 is a frontal sectional view of an example of a stack package module and a lead frame included in the stack package module.

FIG. 2 is a frontal sectional view of an example of stack package module including a plurality of upper packages.

FIG. 3 is a perspective view illustrating side surface grooves in an example of a stack package module.

FIG. 4 is a perspective view illustrating a state in which an example of a lead frame contacts a side surface groove.

FIG. 5 is a perspective view illustrating a state in which an example of a lead frame is coupled to a side surface groove by a solder S.

FIGS. 6 through 9 are cross-sectional views of examples of lead frames.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

In the drawings, the shapes and dimensions of elements may be exaggerated for clarity, and the same reference numerals will be used throughout to designate the same or like elements.

An example of a lead frame 10 and a stack package module including the same connect an upper package 30 and a lower package 20 to each other. According to this example, even if warpage occurs in the upper package 30 or the lower package 20, the coupling of the upper and lower packages 30 and 20 may be maintained, and the formation of an open circuit may be thus prevented.

In addition, the coupling by a solder S, or the like, may be easily performed by positioning a portion of the upper package 30 that connects to the lower package 20 to a side surface of the upper package 30.

Further, a circuit may be connected through the side surface of the upper package 30, and thus a degree of freedom in spatially disposing a component may be increased.

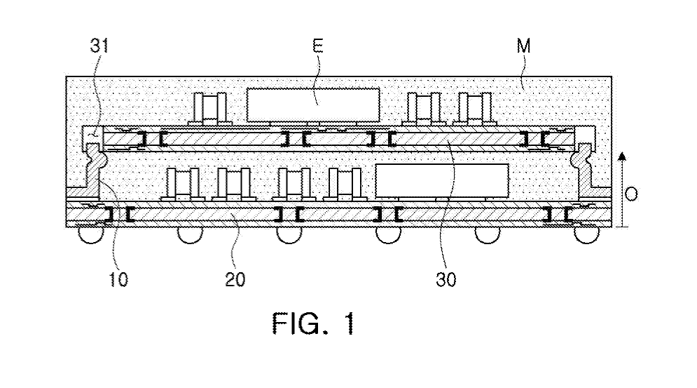

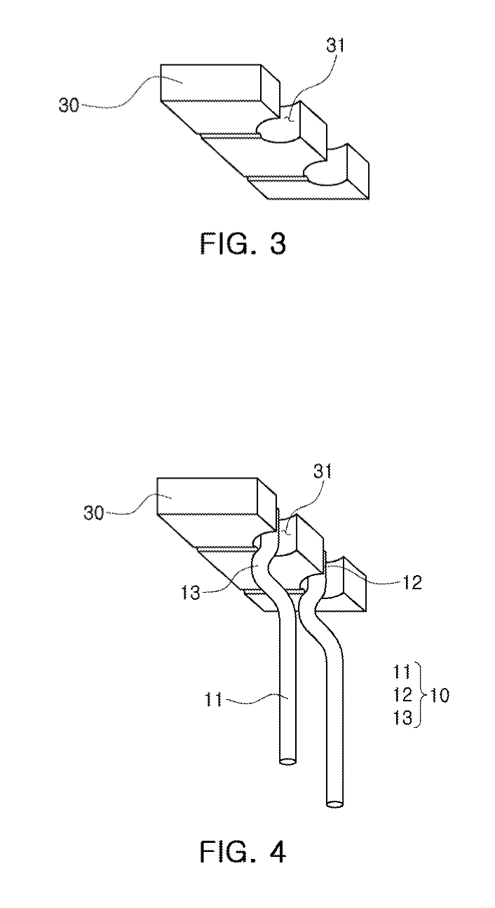

FIG. 1 illustrates an example of a lead frame 10 and a stack package module including the same. FIG. 3 illustrates a perspective view of side surface grooves 31 in the stack package module according to FIG. 1.

Referring to FIGS. 1 and 3, the lead frame 10 includes a lower-end coupling portion 11 coupled to the lower package by the solder S and an upper-end connecting portion 12 that contacts the side surface grooves 31 formed in side surfaces of the upper package 30 to support the upper package 30.

Further, a stack package module according to another example may include a lower package 20, an upper package 30 having a width narrower than that of the lower package 20, and the lead frame 10.

In this example, the lead frame 10 of the stack package module has a length longer than a maximum thickness of elements E mounted on an upper surface of the lower package 20 in a reference (O) direction perpendicular to the upper surface of the lower package 20. However, the present description is not limited thereto.

Further, elements E may be mounted on one surface or both surfaces of the upper package 30 of the stack package module. In this example, the elements E is mounted on one surface of the upper package 3.

FIG. 1 illustrates an example of a lead frame 10 and an example of a stack package module including the lead frame 10.

In this example, the lead frame 10 may perform at least one of a role of electrically connecting the lower package 20 and the upper package 30 to each other and a role of supporting the upper package 30.

To this end, the lead frame 10 includes the lower-end coupling portion 11 and the upper-end connecting portion 12.

The lower-end coupling portion 11 may be a portion coupled to the lower package 20 by the solder S, and formed continuously with the upper-end connecting portion 12.

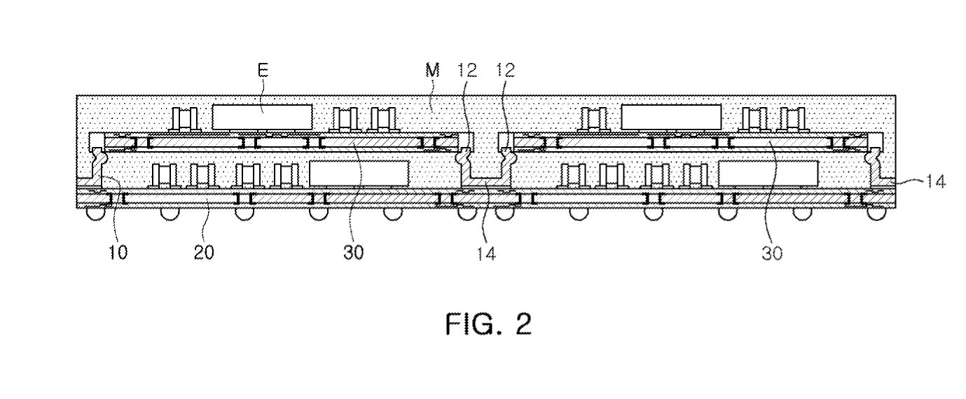

Further, in an example of a stack package module in which a plurality of upper packages 30 are provided, such as the example illustrated in FIG. 2, the lower-end coupling portion 11 may be provided as a single unit in which two or more lower-end coupling portions of the lead frames 10 supporting adjacent upper packages 30 are coupled to each other.

That is, a lower-end coupling portion 11 at one side of one upper package 30 and a lower-end coupling portion 11 at the other side of another upper package may be coupled to each other at a joining portion 14, and thus two or more lead frames 10 may be coupled to the lower package 20 as a single unit. A detailed description thereof will be described below with reference to FIG. 2.

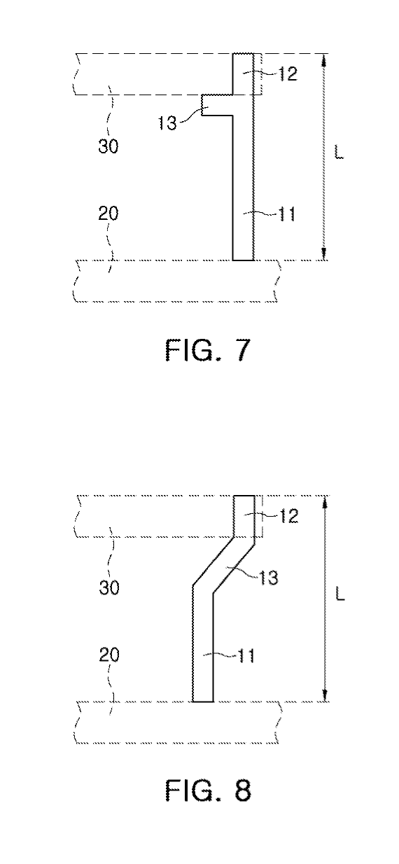

Referring to FIG. 2, the upper-end connecting portion 12 is a portion connected to the upper package 30. In this example, when the upper-end connecting portion 12 is coupled to the side surface groove 31 of the upper package 30 by the solder S, the lead frame 10 electrically connects the upper package 30 and the lower package 20 to each other and supports the upper package 30. A detailed description thereof will be described below with reference to FIG. 5.

Even if the upper-end connecting portion 12 is not coupled to the side surface groove 31 of the upper package 30 by soldering, because the upper-end connecting portion 12 closely adheres to and contacts the side surface groove 31, the upper-end connecting portion 12 stably supports the upper package 30 and electrically connects the upper package 30 to the lower package 20.

That is, the upper-end connecting portion 12 and the side surface groove 31 are electrically connected to each other, and thus the upper package 30 is electrically connected to the lower package 20.

In this example, because the upper-end connecting portion 12 contacts and supports the upper package 30, an elastic force may act on the side surface groove 31. Thus, the upper-end connecting portion 12 supports the upper package 30 while pushing the side surface groove 31, which will be described in detail with reference to FIG. 9.

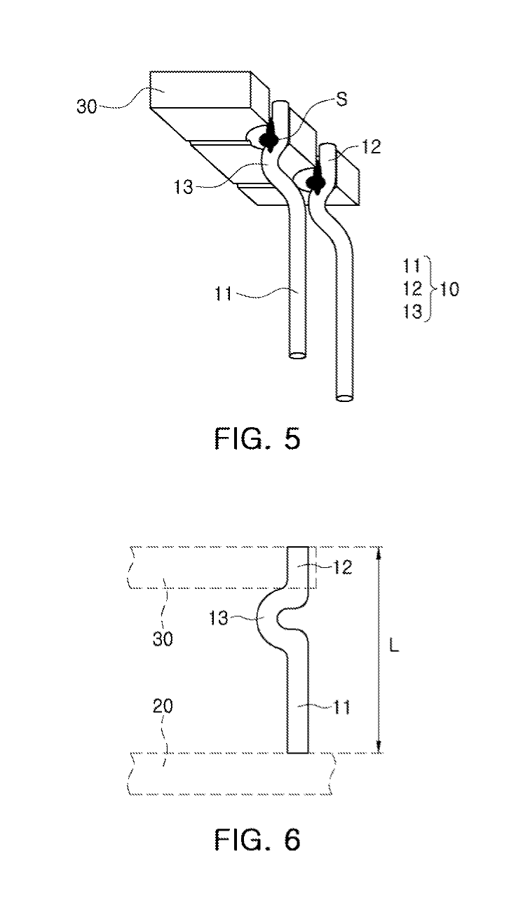

Meanwhile, in order to allow the upper-end connecting portion 12 to closely adhere to the side surface groove 31 and to stably support the upper package 30, the lead frame 10 may further include an intermediate seating portion 13, which will be described in detail with reference to FIG. 4.

In addition, because the lead frame 10 serves to support the upper package 30, there is a need to secure rigidity of the lead frame 10 itself. Thus, in this example, the lead frame 10 is formed to have a thickness t of 0.1 mm or more.

Further, in this example, in order to avoid interference with other wirings, the thickness t of the lead frame 10 is set to be not more than 0.25 mm.

Meanwhile, in order to form an intermediate seating portion 13 to be described below in the lead frame 10, there is a need to secure a total length of the lead frame 10. Thus, in this example, the length of the lead frame 10 is set to be equal to or more than two times the thickness t thereof.

In addition, referring to FIG. 1, the lower package 20 is a package provided in a lower portion of the stack package module. The elements E, which are electronic components, may be mounted on the lower package 20. In order to avoid interference between the mounted elements E and the upper package 30, the lead frame 10 is formed to have a length longer than the maximum thickness of the elements E to be mounted.

That is, the lead frame 10 is provided to have a length longer than the maximum thickness of the elements E mounted on the upper surface of the lower package 20 in the reference (O) direction perpendicular to the upper surface of the lower package 20.

Meanwhile, a molding M is formed on the lower package 20 in order to protect the elements E.

Further, in FIG. 1, the upper package 30 is a package provided above the lower package 20. In this example, elements E are mounted on an upper surface of the upper package 30. However, in another example, elements E may be mounted on one surface or both surfaces of the upper package 30, and thus increasing a mounting area for mounting elements E.

Meanwhile, in an example of a stack package module in which three or more layers of packages are provided, the upper package 30 may also serve as a lower package 20 of a third package provide above the upper package 30. That is, a first upper package 30 may serve as the lower package 20 with respect to a second upper package 30 provided on the first upper package 30.

As described above, the elements E may also be mounted on both surfaces of the upper package 30. Therefore, the elements E mounted on a lower surface of the upper package 30 and the elements E mounted on the upper surface of the lower package 20 may be provided to face each other. In this example, the length of the lead frame 10 in the reference (O) direction is set to be longer than a maximum thickness of the elements E mounted on the lower surface of the upper package 30, and the elements E mounted on the upper surface of the lower package 20 may be formed without interference.

In addition, the side surface groove 31 for forming a connection with the lead frame 10 may be provided in the side surface of the upper package 30. The side surface groove 31 may be formed of a conductive material for electrical connection with the lead frame 10 to thereby be connected to another circuit wiring pattern.

In this example, because the upper package 30 is connected to the lead frame in the side surface groove 31, a soldering process for adhering the solder S to the lead frame 10 may be easily performed. Further, the mounting area of the elements E may be secured by utilizing the side surface of the upper package 30.

Meanwhile, a molding M may be formed on the upper package 20 in order to protect the elements E.

In addition, even if warpage occurs in the upper package 30, because there is a margin of an adhesion portion in the side surface of the upper package 30 in a perpendicular direction, stable adhesion may be secured.

Further, in the event that warpage occurs in the upper package 30, since a position of the upper surface or lower surface of the upper package 30 may be deviated but almost no deviation in position of the side surface thereof is present, a risk of an open-circuit may be further decreased.

FIG. 2 illustrates an example of a stack package module in which a plurality of upper packages are provided. Referring to FIG. 2, a plurality of upper packages 30 are provided on the lower package 20 of the stack package module.

Further, in this example, lower-end coupling portions of the lead frames 10 that extend from upper-end connecting portions 12 connected to two adjacent upper packages 30 among a plurality of upper packages 30 are connected to each other to form a U shape or the like via a joining portion 14. Accordingly to one example, the two adjacent lead frames 10 may be formed integrally out of a single bar member or rod member.

That is, since a lead frame 10 supports an upper package 30 at a side surface of the upper package 30, in order to reduce the effect imposed by the combined weight of the upper package, the upper package 30 may be divided into a plurality of upper packages 30 and provided above the lower package 20.

Further, in an example in which a plurality of upper packages 30 are provided above a lower package 20, a plurality of lead frames 10 may be connected to the upper packages 30 to thereby form a unit.

That is, a plurality of lead frames 10 provided adjacently to each other in order support two adjacent upper packages 30 may be formed integrally or be connected to each other as one unit. In FIG. 2, two adjacent lead frames 10 are integrally formed in a U shape. Thus, number of parts are reduced, and assembling may be easily performed.

In addition, in this example, because the adjacent lead frames 10 may be electrically connected to each other, the upper packages adjacent to each other may be also electrically connected to each other.

The plurality of lead frames 10 as described above may be connected to each other by coupling the lower-end coupling portions of the respective lead frames 10 to each other.

The coupling as described above may be performed by producing the lead frames in a state in which the lead frames are connected to each other at the time of production. Alternatively, respective lead frames 10 may be produced and then additionally connected to each other.

FIG. 4 illustrates a perspective view of an example of lead frame that closely adheres to the side surface groove 31. Referring to FIG. 4, the lead frame 10 includes the intermediate seating portion 13 protruding in a direction different from the reference (O) direction perpendicular to the upper surface of the lower package 20 and provided between the lower-end coupling portion 11 and the upper-end connecting portion 11 so that the upper package 30 may be seated thereon.

In addition, the intermediate seating portion 13 of the lead frame 10 is provided to be closer to the upper-end connecting portion 12 than the lower-end coupling portion 11.

That is, the intermediate seating portion 13 may serve to allow the upper package 30 to seat on the intermediate seating portion 13. To this end, the intermediate seating portion 13 is formed between the upper-end connecting portion 12 and the lower-end coupling portion 11, and protrudes toward the upper package 30.

Further, the intermediate seating portion 13 is formed at a position closer to the upper package 30 than the lower package 20, and thus a space may be secured between the upper package 30 and the lower package 20, whereby a space in which the elements E may be mounted may be secured under the lower surface of the upper package 30.

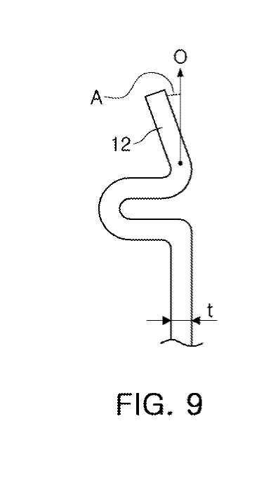

For example, the intermediate seating portion 13 may be formed to protrude in a direction except for the direction perpendicular to the upper surface of the lower package 20, and thus the lead frame 10 may support the upper package 30. A detailed description thereof will be provided with respect to various examples in reference to FIGS. 6 through 9.

FIG. 5 illustrates a perspective view of an example of a lead frame in a state in which the lead frame 10 is coupled to a side surface groove by a solder S. Referring to FIG. 5, the upper-end connecting portion 12 of the lead frame 10 is coupled to the side surface groove 31 by soldering, and the solder S electrically connects the lead frame 10 to the upper package 30.

In this example, when the upper-end connecting portion 12 is coupled to the side surface groove 31 of the upper package 30 by the solder S, the lead frame 10 may electrically connect the upper package 30 and the lower package 20 to each other and support the upper package 30.

In addition, the lead frame 10 may be coupled to the side surface groove 31, which may secure an area in which the elements E may be mounted on the upper package 30. Further, in view of a process, the soldering of the lead frame 10 to the side surface of the upper package 30 may be more easily performed than the soldering of the lead frame 10 a lower surface of the upper package 30.

FIGS. 6 through 9 illustrate various examples of lead frames. First, FIG. 6 illustrates an example of a lead frame 10 of which an intermediate seating portion 13 is formed in a laid “U” shape. FIG. 7 illustrates an example of a lead frame 10 of which an intermediate seating portion 13 is formed in a laid “I” shape as to protrude from a side of the lead frame 10.

Referring to FIGS. 6 and 7, the intermediate seating portion 13 of the lead frame 10 may be formed so that the lower-end coupling portion 11 and the upper-end connecting portion 12 are positioned on the same axis in the reference (0) direction, and the intermediate seating portion 13 may be provided to protrude toward the upper package 30.

Further, the intermediate seating portion 13 of the lead frame 10 may be provided in the laid “U” shape or the laid “I” shape.

In addition, the lead frame 10 according to the stack package module may be formed of a bar member or an angular rod member.

That is, the intermediate seating portion 13 may be formed to protrude toward the upper package 30, and thus the upper package 30 may be seated on and supported by the intermediate seating portion 13.

In relation to a protrusion shape of the intermediate seating portion 13 as described above, the lower-end coupling portion 11 and the upper-end connecting portion 12 may be disposed on the same axis in the reference (O) direction perpendicular to the upper surface of the lower package 20, and the intermediate seating portion 13 may have the laid “U” shape so as to protrude in a curved shape, or may have the laid “I” shape so as to protrude in a step shape.

The laid “U” shape may be formed by bending a material provided as the bar member or the angular rod member.

In addition, the laid “I” shape may be formed by allowing the material provided as the bar member or the angular rod member to protrude toward one side like a bough.

In addition, FIG. 8 illustrates an example of a lead frame 10 having an intermediate seating portion 13 that is inclined with respect to an axial direction of the lead frame 10, and FIG. 9 illustrates an example of a lead frame 10 in which an upper-end connecting portion 12 is formed to be inclined toward the upper package 30.

Referring to FIG. 8, the intermediate seating portion 13 of the lead frame 10 is inclined with respect to the reference (O) direction, or the axial direction of the lead frame 10, so that the lower-end coupling portion 11 may be positioned inwardly of the upper-end connecting portion 12 in a direction parallel with the upper package 30.

In addition, the upper-end connecting portion 12 of the lead frame 10 is provided to be inclined toward the upper package 30 from the reference (O) direction perpendicular to the upper surface of the lower package 20.

In order to provide an inclined intermediate seating portion, the lower-end coupling portion 11 and the upper-end connecting portion 12 may not be provided on the same axis in the reference (O) direction. That is, in order to provide the intermediate seating portion 13 to be inclined, the lower-end coupling portion 11 and the upper-end connecting portion 12 need to be provided on different axes from each other in the reference (O) direction.

Further, in order to allow the intermediate seating portion 13 to support the upper package 30, the lower-end coupling portion 11 needs to be positioned inwardly in the direction parallel with the upper package 30, and the upper-end connecting portion 12 needs to be position outwardly of the lower-end coupling portion 11 in the direction parallel with the upper package 30.

Meanwhile, the upper-end connecting portion 12 may be formed to be inclined toward the upper package 30. This is to provide elastic force pressing the side surface of the upper package 30 to increase reliability of electrical connection with the upper package 30 and support the upper package 30.

In one example, the inclined portion may form an angle A toward the upper package 30 within 10 degrees with respect to the reference (O) direction. That is, the inclined portion forms a slope with an angle greater than 0 degree with respect to the axial direction of the upper-end connection portion 12 or the lower-end coupling portion 11 of the lead frame 10.

As set forth above, according to one example of a lead frame and a stack package module including the same, even if warpage occurs in the upper package or the lower package, the coupling may be maintained, and thus the formation of an open-circuit may be prevented.

In addition, the coupling such as the soldering, or the like, may be easily performed by setting the portion of the upper package connected to the lower package to a side surface of the upper package.

Further, the circuit may be connected through a side surface of the upper package 30, and thus a degree of freedom in spatially disposing a component may be increased.

In addition, the lead frame may be capable of easily connecting upper and lower packages and of preventing a risk of an open-circuit, thus improving the reliability of a stack package module including the same.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A lead frame comprising:
a lower-end coupling portion coupled to a lower package through soldering; and
an upper-end connecting portion contacting a side surface groove formed in a side surface of an upper package to support the upper package.

2. The lead frame of claim 1, further comprising an intermediate seating portion disposed between the lower-end coupling portion and the upper-end connecting portion, the intermediate seating portion protruding in a direction different from a reference direction perpendicular to an upper surface of the lower package so as to allow the upper package to be seated thereon.

3. The lead frame of claim 2, wherein the intermediate seating portion is closer to the upper-end connecting portion than the lower-end coupling portion.

4. The lead frame of claim 3, wherein the intermediate seating portion is formed so that the lower-end coupling portion and the upper-end connecting portion are aligned along a same axis in the reference direction, and
the intermediate seating portion protrudes toward the upper package.

5. The lead frame of claim 4, wherein the intermediate seating portion has a laid “U” shape or a laid “I” shape.

6. The lead frame of claim 3, wherein the intermediate seating portion comprises an inclined portion that is inclined with respect to the reference direction so that the lower-end coupling portion is positioned inwardly of the upper-end connecting portion in a direction parallel with the upper package.

7. The lead frame of claim 1, wherein the upper-end connecting portion is inclined toward the upper package from a reference direction perpendicular to an upper surface of the lower package.

8. The lead frame of claim 1, wherein the upper-end connecting portion is coupled to the side surface groove through soldering.

9. A stack package module comprising:
a lower package;
an upper package having a width narrower than a width of the lower package; and
the lead frame of claim 1.

10. The stack package module of claim 9, wherein the lead frame comprises a bar member or an angular rod member.

11. The stack package module of claim 9, wherein the lead frame has a length longer than a maximum thickness of elements mounted on an upper surface of the lower package in a reference direction perpendicular to the upper surface of the lower package.

12. The stack package module of claim 9, wherein a plurality of upper packages are disposed above the lower package.

13. The stack package module of claim 12, wherein the upper packages are each supported by corresponding lead frames, and
lower-end coupling portions extended from upper-end connecting portions contacting two adjacent upper packages among the plurality of upper packages are connected to each other.

14. The stack package module of claim 9, wherein elements are mounted on one surface or both surfaces of the upper package.

15. A stack package module comprising:
a first package;
a second package dispose above the first package, the second package comprising a side surface groove; and
a lead frame coupled to the first package and extending to the side surface groove of the second package to support the second package above the first package.

16. The stack package module of claim 15, wherein the lead frame comprises an intermediate seating portion protruding toward a side direction to support the second package.

17. The stack package module of claim 16, wherein the intermediate seating portion comprises a bent portion having at least one of a laid “U” shape, an inclined portion and a laid “I” shape.
